(19) United States
(12) Patent Application Publication
(10) Pub. No.: US 2012/0090775 A1
(43) Pub. Date: Apr. 19, 2012

(54) MANUFACTURING PROCESSES FOR SURFACE TREATMENT

(76) Inventor: Dong-Ge CHENG, Xinzhuang City (TW)

(21) Appl. No.: 12/903,265

(22) Filed: Oct. 13, 2010

(51) Int. Cl. B44C 1/17; C23C 14/14; C23C 14/34; B05D 3/06; C25D 5/56

(52) U.S. Cl. 156/237; 427/555; 427/556; 205/164; 204/192.1

(57) ABSTRACT

The present invention provides several manufacturing processes for surface treatment in order to improve conventional electroplating, coating, sputtering processes. Through the surface treatment of the present invention, a brilliant modern pattern/mark can be achieved. Pearl luster lacquer coating, non-pearl luster lacquer coating and laser-marking are the characteristics of the present invention.

### FIELD OF THE INVENTION

The present invention relates to manufacturing processes for surface treatment of metal or plastic materials, and more particularly to manufacturing processes for surface treatment by pearl luster lacquer coating, non-pearl luster lacquer coating and laser-marking.

### BACKGROUND OF THE INVENTION

Conventional manufacturing processes for surface treatment of metal or plastic materials are electroplating, coating and sputtering, these manufacturing processes are used for surface treatment of the cases of 3C products in order to produce smooth surface.

U.S. Pat. No. 6,545,065 disclosed a novel plastic product, in which pearl luster pigments and/or non-lustrous metal oxide-coated mica pigments are mixed into the plastic, and then laser-marking are used for marking varieties of patterns/marks on the plastic.

There are two kinds of pearl luster pigmemt, one is the powder of natural pearl, the other is made by mixturing and high temperature forging of mica and some of the materials selected from the group consisting of SiO₂, Fe₂O₃, TiO₂, BaSO₄, SnO₂, BiOCl, Cr₂O₃ to form materials of different colors and show brilliant property. Cosmetics and lipstick consist pearl luster pigmemt so as to show colorful and gorgeous properties. Pearl luster lacquer is a mixture of pearl luster pigmemt and clear paint. By coating the pearl luster lacquer on the surface of the case of 3C product, a brilliant and modern feeling will be achieved.

### SUMMARY OF THE INVENTION

The object of the present invention is to provide manufacturing processes for surface treatment, which is very different from conventional electroplating, coating and sputtering, in which pearl luster lacquer coating, non-pearl luster lacquer coating and laser-marking are the characteristics of the present invention. Using the manufacturing processes for surface treatment of the present invention to generate varieties of patterns/marks, a brilliant and modern feeling will be achieved. The manufacturing processes for surface treatment of the present invention are described as below:

### A. Manufacturing Process for Surface Treatment of Metal or Plastic Materials:

Step 1: a layer of pearl luster lacquer or a plurality of layers of pearl luster lacquer with different colors are coated on the metal or plastic materials, and then a non-pearl luster lacquer are coated on (this process can be omitted); or the pearl luster lacquer and the non-pearl luster lacquer are coated in turns on the metal or plastic materials;

Step 2: scraping the pearl luster lacquer or the non-pearl luster lacquer coated in step 1 by laser-marking in order to show one layer of the pearl luster lacquer or the non-pearl luster lacquer which is wanted to display;

Step 3: a layer of clear paint is then coated on the surface of the metal or plastic materials.

### B. Manufacturing Process for Surface Treatment of Transparent Plastic Material:

Step 1: a layer of pearl luster lacquer is coated on the back of the transparent plastic material or a layer of copper, chromium, or nickel is eletroplated on the back of the transparent plastic material or a layer of titanium, chromium, aluminum or tin is sputtered on the back of the transparent plastic material;

Step 2: a layer of pearl luster lacquer or a plurality of layers of pearl luster lacquer with different colors are coated on the front of the transparent plastic material; or the pearl luster lacquer and the non-pearl luster lacquer are coated in turns on the front of the transparent plastic material;

Step 3: scraping the pearl luster lacquer or the non-pearl luster lacquer coated in step 2 by laser-marking in order to show the pearl luster lacquer, eletroplated material or sputtered material on the back of the transparent plastic material or show one layer of the pearl luster lacquer or the non-pearl luster lacquer in step 2 which is wanted to display;

Step 4: a layer of clear paint is then coated on the front of the transparent plastic material.

### C. Another Manufacturing Process for Surface Treatment of Plastic Material:

Step 1: a layer of copper, chromium, or nickel is eletroplated on the plastic material or a layer of titanium, chromium, aluminum or tin is sputtered on the plastic material;

Step 2: a layer of pearl luster lacquer or a plurality of layers of pearl luster lacquer with different colors are coated on the plastic material; or the pearl luster lacquer and the non-pearl luster lacquer are coated in turns on the plastic material;

Step 3: scraping the pearl luster lacquer or the non-pearl luster lacquer coated in step 2 by laser-marking in order to show the pearl luster lacquer, the non-pearl luster lacquer, the eletroplated material or sputtered material;

Step 4: a layer of clear paint is then coated on the plastic material.

### DETAILED DESCRIPTIONS OF THE PREFERRED EMBODIMENTS

In order to generate varieties of brilliant and colorful patterns/symbols on the surface of metal or plastic products, the present invention provides manufacturing processes for surface treatment of metal or plastic materials as below:

### A. Manufacturing Process for Surface Treatment of Metal or Plastic Materials:

Step 1: a layer of pearl luster lacquer or a plurality of layers of pearl luster lacquer with different colors are coated on the metal or plastic materials, and then a non-pearl luster lacquer are coated on (this process can be omitted); or the pearl luster lacquer and the non-pearl luster lacquer are coated in turns on the metal or plastic materials;

Step 2: scraping the pearl luster lacquer or the non-pearl luster lacquer coated in step 1 by laser-marking in order to show one layer of the pearl luster lacquer or the non-pearl luster lacquer which is wanted to display;

Step 3: a layer of clear paint is then coated on the surface of the metal or plastic materials.

In which the step2 and the step 3 can be exchanged.

### B. Manufacturing Process for Surface Treatment of Transparent Plastic Material:

Step 1: a layer of pearl luster lacquer is coated on the back of the transparent plastic material or a layer of copper, chromium, or nickel is eletroplated on the back of the transparent plastic material or a layer of titanium, chromium, aluminum or tin is sputtered on the back of the transparent plastic material;

Step 2: a layer of pearl luster lacquer or a plurality of layers of pearl luster lacquer with different colors are coated on the front of the transparent plastic material; or the pearl luster lacquer and the non-pearl luster lacquer are coated in turns on the front of the transparent plastic material;

Step 3: scraping the pearl luster lacquer or the non-pearl luster lacquer coated in step 2 by laser-marking in order to show the pearl luster lacquer, eletroplated material or sputtered material on the back of the transparent plastic material or show one layer of the pearl luster lacquer or the non-pearl luster lacquer coated in step 2 which is wanted to display;

Step 4: a layer of clear paint is then coated on the front of the transparent plastic material.

In which the step3 and the step 4 can be exchanged.

### C. Another Manufacturing Process for Surface Treatment of Plastic Material:

Step 1: a layer of copper, chromium, or nickel is eletroplated on the plastic material or a layer of titanium, chromium, aluminum or tin is sputtered on the plastic material;

Step 2: a layer of pearl luster lacquer or a plurality of layers of pearl luster lacquer with different colors are coated on the plastic material; or the pearl luster lacquer and the non-pearl luster lacquer are coated in turns on the plastic material;

Step 3: scraping the pearl luster lacquer or the non-pearl luster lacquer coated in step 2 by laser-marking in order to show the pearl luster lacquer, the non-pearl luster lacquer, the eletroplated material or sputtered material;

Step 4: a layer of clear paint is then coated on the plastic material.

In which the step 3 and the step 4 can be exchanged.

The pearl luster lacquer is a mixture of pearl luster pigmemt and clear paint. There are two kinds of clear paint, one is greasy clear paint, the other is aqueous clear paint. Both of the two clear paints can be used in the present invention.

Greasy clear paint is a mixture of resin, additive and solvent. For example, resins are Thermoplastic Acrylic Resin, Polyols for Two Component PU Resin, Acrylic Polyol Resin, etc. Additives are leveling agent, slip additive, antifoamer. Solvents are EAC, Toluene, N-Butyl acetate, MIBK, BCS, DIBK, BAC.

Aqueous clear paint is a mixture of denaturation resin, additive and alcohol, and is diluted by water when coating. For example, denaturation resin is denaturation acrylic resin, in which the functional group of the acrylic is changed into hydrophilic group.

Non-pearl luster lacquer is a lacquer without pearl luster pigmemt, and is a mixture of resin, toner, additive and solvent.

There are five kinds of laser for laser-marking, including air-cooling diode exciting laser, water-cooling diode exciting laser, CO₂ exciting laser, fiber-optic exciting laser and lamp-pumped Nd:YAG laser. By controlling power, frequency, speed and spacing of the laser to adjust the depth of the engraving, a needed pattern can be formed.

The laser-marking machine used by the present invention is a water-cooling diode exciting laser with model no. DPY-50W made by “EASYLIGHT E-O Tech. Co., Ltd.” (Address: 1F., No. 506, Jianguo Rd., Yingge Township, Taipei County 239, Taiwan; TEL: +886 2 2679 6521). Other related products made by “Leader Precision Technology Co. Ltd.”, “Action Laser Technology Co. Ltd.” and “Signgrafs Technology Co. Ltd.” can also be used.

A laser film transfer printing process can be added before or after the laser-marking process in the three manufacturing processes of the present invention mentioned above. The laser film transfer printing process is a process to form a film by electroplating a layer of resin on PET or OPP, and then let the film be press printed on metal or plastic by a laser mould.

Pearl luster lacquer coating, non-pearl luster lacquer coating and laser-marking are the characteristics of the present invention. Pearl luster lacquer comprises pearl luster pigments to generate brilliant colors; laser-marking is used for marking varieties of patterns/marks on the plastic case of 3C products to achieve a brilliant and modern feeling.

The scope of the present invention depends upon the following claims, and is not limited by the above embodiments.

What is claimed is:

1. A manufacturing process for surface treatment of metal or plastic materials, comprising steps as below:
a. a layer of pearl luster lacquer or a plurality of layers of pearl luster lacquer with different colors are coated on the metal or plastic materials, and then a non-pearl luster lacquer are coated on; or the pearl luster lacquer and the non-pearl luster lacquer are coated in turns on the metal or plastic materials;
b. scraping the pearl luster lacquer or the non-pearl luster lacquer coated in step a by laser-marking in order to show one layer of the pearl luster lacquer or the non-pearl luster lacquer which is wanted to display;
c. a layer of clear paint is then coated on the surface of the metal or plastic materials.

2. A manufacturing process for surface treatment of transparent plastic material, comprising steps as below:
a. a layer of pearl luster lacquer is coated on the back of the transparent plastic material or a layer of copper, chromium, or nickel is eletroplated on the back of the transparent plastic material or a layer of titanium, chromium, aluminum or tin is sputtered on the back of the transparent plastic material;
b. a layer of pearl luster lacquer or a plurality of layers of pearl luster lacquer with different colors are coated on the front of the transparent plastic material; or the pearl luster lacquer and the non-pearl luster lacquer are coated in turns on the front of the transparent plastic material;
c. scraping the pearl luster lacquer or the non-pearl luster lacquer coated in step b by laser-marking in order to show the pearl luster lacquer, eletroplated material or sputtered material on the back of the transparent plastic material or show one layer of the pearl luster lacquer or the non-pearl luster lacquer coated in step b which is wanted to display;
d. a layer of clear paint is then coated on the front of the transparent plastic material.

3. A manufacturing process for surface treatment of plastic material, comprising steps as below:
a. a layer of copper, chromium, or nickel is eletroplated on the plastic material or a layer of titanium, chromium, aluminum or tin is sputtered on the plastic material;
b. a layer of pearl luster lacquer or a plurality of layers of pearl luster lacquer with different colors are coated on the plastic material; or the pearl luster lacquer and the non-pearl luster lacquer are coated in turns on the plastic material;
c. scraping the pearl luster lacquer or the non-pearl luster lacquer coated in step b by laser-marking in order to show the pearl luster lacquer, the non-pearl luster lacquer, the eletroplated material or sputtered material;
d. a layer of clear paint is then coated on the plastic material.

4. The manufacturing process for surface treatment according to claim 1, wherein the step b and the step c are exchanged.

5. The manufacturing process for surface treatment according to claim 2, wherein the step c and the step d are exchanged.

6. The manufacturing process for surface treatment according to claim 3, wherein the step c and the step d are exchanged.

7. The manufacturing process for surface treatment according to claim 1, wherein the process of “and then a non-pearl luster lacquer are coated on” is omitted.

8. The manufacturing process for surface treatment according to claim 1, wherein a laser film transfer printing process is added before or after the step b.

9. The manufacturing process for surface treatment according to claim 2, wherein a laser film transfer printing process is added before or after the step c.

10. The manufacturing process for surface treatment according to claim 3, wherein a laser film transfer printing process is added before or after the step c.
